(19) United States
(12) Patent Application Publication
(10) Pub. No.: US 2004/0155669 A1
(43) Pub. Date: Aug. 12, 2004

(54) Proximity switch with display means and application process of such a switch

(76) Inventors: Remy Kirchdoerffer, Reichshoffen (FR); Ralf Schmidt, Freinsheim (DE); Gerd Ebelt, Freinsheim (DE)

Correspondence Address: YOUNG & THOMPSON, 745 SOUTH 23RD STREET 2ND FLOOR, ARLINGTON, VA, 22202

(21) Appl. No.: 10/698,475

(22) Filed: Nov. 3, 2003

(30) Foreign Application Priority Data
Jun. 19, 2002 (EP) 02360183.4

(51) Int. Cl. G01R 27/26

(52) U.S. Cl. 324/668; 324/661

(57) ABSTRACT

A proximity switch which operates according to an inductive or capacitive action principle and contains a LC tuned circuit and a dynamically connected amplifier, and in which the approach of a suitable influencing element or article changes at least one oscillation parameter, the operating state of the amplifier being changed when the article does not reach a certain distance to the tuned circuit, the oscillation not however being interrupted with reaching the operating point. The proximity switch (1), likewise contains display elements (5) which are able to signal the presence of influence on the tuned circuit before the operating point or value of the amplifier is reached.

This invention relates to the field of scanning and detection of the position and optionally the motion of an article which for example influences electromagnetic fields, and relates to a capacitive or inductive proximity switch or sensor, and an application process of such a switch or sensor.

Sensors which operate using an inductive and capacitive action principle usually have LC tuned circuits, the “L” coil facing the active surface, and the coil can be influenced in its properties by an external influencing, especially damping, for example metallic, element.

The LC tuned circuit forms an oscillating system which oscillates automatically at a certain frequency. By influencing the coil there are no longer free oscillation conditions so that the oscillation attenuates or is interrupted until the damping element is moved farther away or eliminated and the oscillator can again continue to oscillate or build-up.

Sensors of this type are known especially from EP applications No. 01440262.2, No. 01440311.7 and No. 01440399.2.

But adjustments of these sensors, depending on the specifics of the various possible applications, can be very time-consuming and delicate.

In particular, the installer has no information about how sensitive the installed sensor is, i.e. how close it is to the operating point in the absence of any influence.

Furthermore it is not possible to take into account a change of the potentially influencing environment.

At this point it must be noted that in any case, there is influencing of the sensor (by the environment) without the element to be detected being present or being located at a distance which cannot be detected.

The critical point here is that the intensity of this “prior influencing”, depending on the application, is very different, that thus the sensor in some cases can be located in a state near the operating point.

In the prior art this situation is not taken into account in a suitable manner.

The object of this invention is to devise a proximity switch or sensor which is able to eliminate at least some of the aforementioned defects.

The invention among others is intended to enable signalling (as a display or switching output) of a range which, before reaching the operating point, shows that there is an influence, and optionally communicates shortly after the operating point that it has only barely been reached.

In this regard the invention relates to a proximity switch or sensor which operates according to an inductive or capacitive action principle and contains a LC tuned circuit and a dynamically connected amplifier, and in which the approach of a suitable influencing element or article changes at least one oscillation parameter, the operating state of the amplifier being changed when the article does not reach a certain distance to the tuned circuit, the free oscillation, or for example, the oscillation which is for example externally excited by a pulse not however being interrupted with reaching the operating point, or at least not immediately, characterized in that it likewise contains display means which are able to signal the presence of influence on the tuned circuit before the operating point or value of the amplifier is reached.

Thus, the signalling is determined over “n” events, with n≧1 and can thus report one-time events up to events which have been overly filtered.

Moreover signalling can be expressed in different forms, as for example an audio signal, light signal, delivery of a message, switching signal, etc.

According to one advantageous feature of the invention the display means are also active, i.e. signal the presence of an influence on the tuned circuit, when the operating point has been reached and exceeded.

According to a first version of the invention, the display means can be adjusted such that they are active when the intensity of the influence on the tuned circuit is within at least one sensing range which surrounds and contains the intensity value which corresponds to the operating point.

According to another alternative version of the invention, the display means can be active as long as the intensity of the influence on the tuned circuit is above a first lower bottom threshold value and below a second higher top threshold value, these threshold values surrounding the intensity value which corresponds to the operating point on both sides.

Advantageously the bottom and top threshold value are roughly 5% to 20%, preferably roughly 10%, below and above the intensity value which corresponds to the operating point.

The sensor or the confirmation element is preferably set such that reliable operation of the sensor is guaranteed over its tolerance range (for example, the temperature function range).

According to standards relating to the range of operating distances of inductive sensors the following sensing distance deviations are tolerated (Sn=nominal sensing distance):

tolerance due to dispersion: +/−10%,

action of temperature: +/−10%.

Thus the signalling as claimed in the invention should take place over the range: 0.81 Sₙ to 1.21 Sₙ.

In order to discover the location of the influencing level relative to the operating value, the display means, when they are active, can deliver various signals (for example, two different signals) depending on whether the intensity of the influence on the tuned circuit has exceeded the intensity value which corresponds to the operating point or not.

The parameters used to evaluate the influence on the tuned circuit can be chosen from the group which contains amplitude, phase and frequency.

According to one practical approach as claimed in the invention, the signal delivered by the display means is a signal of any shape, for example a rectangular pulse signal, which indicates the state or the point of instantaneous intensity of the influence on the tuned circuit relative to the sensing range and/or the threshold values statically, dynamically, with a time delay or by means of the action of another function.

So that the display means can adapt to different electromagnetic environments and can also deliver a signal which can be easily evaluated, the sensing range which corresponds to the active state of the display means, or the threshold values can be adjusted, the display means containing a switching amplifier or a switching amplifier being dynamically connected in series to these display means.

The subject matter of the invention is likewise an application process of a proximity switch or sensor as was described above.

This process has mainly the following steps:

mounting of the housing which contains the switch or sensor at the application site;

execution of a calibration or adjustment process of the switch or sensor, specifically of the tuned circuit and the display means, and the optionally dynamically connected electronics (for example, amplifier), in the presence of a working environment which is conventional in the application, but in the absence of the influencing element or article which is to be detected in the working process, at least by moving out of the detection range of the switch or sensor;

use of an adjusted switch or sensor as a proximity switch, after completion of the preceding steps.

According to one preferred development of the invention it can be provided that the calibration or adjustment process is repeated, for example after any change of the working environment of the switch or sensor, while the influencing element is far outside of the detection range.

In the following specification the invention is detailed using embodiments in conjunction with the attached schematic figures.

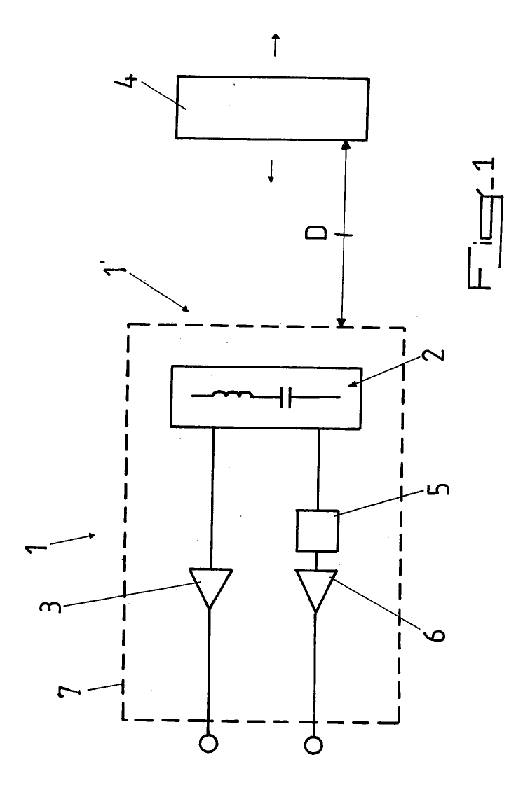

FIG. 1 shows a schematic block diagram of a proximity switch as claimed in the invention;

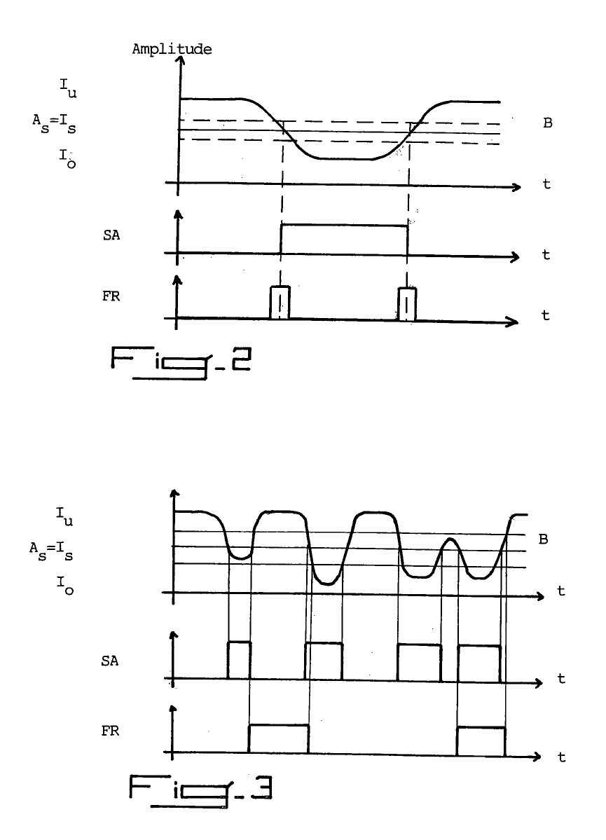

FIG. 2 shows synchronous time diagrams which illustrate the developments of the amplitude, the output signal SA of the sensor (switching amplifier) and the output signal SR of the display means (switching amplifier), in the case of strong electromagnetic influence by a suitable element, according to a static evaluation of the influence by the display means;

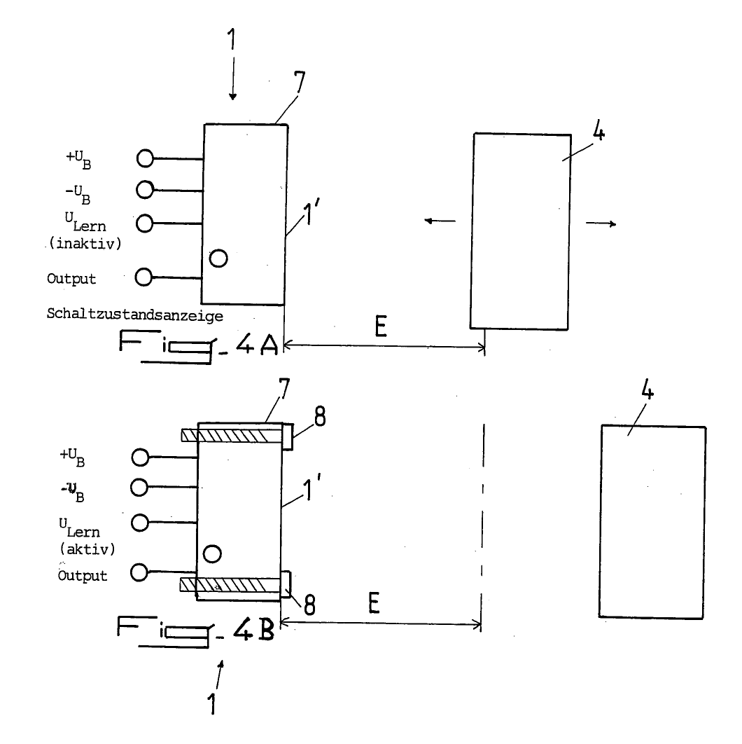

FIG. 3 shows synchronous time diagrams which illustrate the developments of the amplitude, the output signal SA of the sensor and the output signal SR of the display means in the case of repeated strong electromagnetic influences on the tuned circuit by a suitable element, according to a dynamic evaluation of the influence by the display means;

FIGS. 4A and 4B show schematics of the proximity switch or sensor and of the corresponding influencing element which illustrate their relative position during normal working operation and during the adjustment process.

As follows from FIGS. 1, 4A and 4B, it is a proximity switch or sensor 1 which works using a capacitive or inductive action principle and contains a matched LC tuned circuit 2.

By the approach, from the side of the active surface 1′, of a material which influences electromagnetic fields, when the article 4 made of these materials or bearing this material does not reach a given distance D, the switching state of the switching amplifier 3 which is dynamically connected to the tuned circuit 2 is changed.

The tuned circuit 2 is designed and excited such that the corresponding oscillator oscillation is not interrupted when the operating point is reached.

As already indicated, there are additional display means 5 which are able to signal that even before reaching the operating point there is an influence by the presence or approach of a material which influences the electromagnetic field, this signalling being extinguished or becoming inactive only when the series-connected switching amplifier 3 has reliably changed its operating state.

Thus, a safety range B is defined which is preset or adjustable and is for example laid out such that the display arrives 10% before the operating point and the display is extinguished 10% after the operating point.

In FIGS. 2 and 3 these threshold values are given as Iu and Io and delineate a sensing range B (safety range).

The function reserve display which has been determined in this way can operate statically, dynamically or with a time delay, or can be subject to other time functions.

Moreover, these display means 5 can be provided with a series-connected switching amplifier 6 in order to detect changes in the sensor environment early, with or without the display, such as for example welding spatters on the sensor surface 1′.

Furthermore the sensitivity of the coil system of the tuned circuit can be adjusted to external influences as always by the user (“Poti Teach In” or the like) and optionally the sensor 1 can change its sensitivity setting itself by suitable algorithms and adapt to the existing requirements.

The above explained signalling can be used for various purposes:

a) mechanical setting or calibration in the application becomes more reliable because critical ranges around the operating point are avoided if for example a BE (influencing element) is to be recognized, without the BE the background already leading to influences, thus both the operating threshold and also the gain can be optimized to the application.

b) influences by the environment which adversely affect the operation of the sensor, and threaten to lead to false alarms, are detected in time in the phase in which the sensor still has its complete function,

c) the sensitivity can be permanently tracked within certain limits (self-learning), for example in case of fouling by welding spatters.

This signalling can be used especially to improve the sensitivity of an inductive or capacitive sensor by assimilating the environment.

In fact, for an inductive sensor 1 with especially long range (detection range E), i.e. with high sensitivity, its behavior can change adversely in an altered environment.

If for example metal parts are located in the vicinity or the sensor 1 is installed with metal screws 8 (by its housing 7), under certain circumstances as a result of this altered environment an output signal which would correspond to a detected object could be delivered. The sensor 1 would then consequently exhibit a malfunction.

Accordingly it becomes difficult to uniformly optimize a sensor 1 of such high sensitivity for some application, therefore for various customers. In agreement with the invention this results in the consideration that this sensor 1 must assimilate the application environment by means of an adjustment process.

The environment is assimilated selectively either automatically after turning on as a so-called “power-up function” or a control line is defined in order to be able to initiate the assimilation process at any time with a control signal Uₗₑₐᵣₙ. During this phase the user must ensure that the object to be detected (article 4) is located far outside the range E of operating distances (detection range) of the sensor 1. All other metal parts in the vicinity of the sensor 1 are now recognized as its “natural environment” and assimilated.

In the sensor 1, during “assimilation operation”, adaptation of the operating threshold (As=Is) takes place internally, this according to the environment-induced change of the magnetic field produced by the sensor 1. This threshold is stored in the sensor 1 at the end of the assimilation process. It is then used later, during “working operation”, as a comparison threshold (As=Is).

If the detected signal change during working operation is smaller than the signal change caused beforehand by the environment (this corresponds to the stored threshold value), “no object [is] recognized”. In the other case, for a larger signal change “the object [is] recognized”. The sensor 1 changes the operating state when this threshold is exceeded.

In addition, it should be noted that although the invention has been described in conjunction with a sensor 1, it can also be easily used in a so-called interrogation set.

Of course the invention is not limited to the described embodiments. Modifications, for example in the embodiments of the various components, or replacements by technical equivalents are possible at any time if they remain within the framework of the claimed application.

1. Proximity switch or sensor which operates according to the inductive or capacitive action principle and contains a LC tuned circuit and a dynamically connected amplifier, and in which the approach of a suitable influencing element or article changes at least one oscillation parameter, the operating state of the amplifier being changed when the article does not reach a certain distance to the tuned circuit, the free or externally excited oscillation not however being interrupted with reaching the operating point, or at least not immediately, characterized in that it likewise contains display means (5) which are able to signal the presence of influence on the tuned circuit (2) before the operating point or value of the amplifier (3) is reached.

2. Proximity switch as claimed in claim 1, wherein the display means (5) are also active, i.e. signal the presence of an influence on the tuned circuit (2), when the operating point has been reached and exceeded.

3. Proximity switch as claimed in one of claims 1 and 2, wherein the display means (5) are adjusted such that they are active when the intensity of the influence on the tuned circuit (2) is within at least one sensing range (13) which surrounds and contains the intensity value (Is) which corresponds to the operating point.

4. Proximity switch as claimed in one of claims 1 and 2, wherein the display means (5) are active as long as the intensity of the influence on the tuned circuit (2) is above a first lower bottom threshold value (Iu) and below a second higher top threshold value (Io), these threshold values (Is) surrounding the intensity value (Is) which corresponds to the operating point (on both sides).

5. Proximity switch as claimed in claim 4, wherein the bottom and top threshold value (Iu, Io) are roughly 5% to 20%, preferably roughly 10%, below and above the intensity value (Is) which corresponds to the operating point.

6. Proximity switch as claimed in one of claims 3 to 5, wherein the display means (5), when they are active, deliver various signals depending on whether the intensity of the influence on the tuned circuit (2) has exceeded the intensity value (Is) which corresponds to the operating point or not.

7. Proximity switch as claimed in one of claims 3 to 6, wherein the parameter which is used to evaluate the influence on the tuned circuit (2) is chosen from the group which contains amplitude, phase and frequency, and wherein the signal delivered by the display means (5) is a signal of any shape, for example a rectangular pulse signal which indicates the state or the point of instantaneous intensity of the influence on the tuned circuit (2) relative to the sensing range (B) and/or the threshold values (Iu, Io) statically, dynamically, with a time delay or by means of the action of another function.

8. Proximity switch as claimed in one of claims 3 to 7, wherein the sensing range (B) or the threshold values can be adjusted and wherein the display means (5) contain a switching amplifier (6) or wherein a switching amplifier (6) is dynamically connected in series to these display means (5).

9. Application process of a proximity switch or sensor as claimed in one of claims 1 to 8, wherein it has mainly the following steps:
mounting of the housing (7) which contains the switch or sensor (1) at the application site;
execution of a calibration or adjustment process of the switch or sensor (1), specifically of the tuned circuit (2) and the display means (5), and the optionally dynamically connected electronics (3, 6), in the presence of a working environment which is conventional in the application, but in the absence of the influencing element or article (4) which is to be detected in the working process, at least by moving out of the detection range (E) of the switch or sensor (1);
use of an adjusted switch or sensor (1) as a proximity switch, after completion of the preceding steps.

10. Application process as claimed in claim 9, wherein the calibration or adjustment process is repeated, for example after any change of the working environment of the switch or sensor (1), while the influencing element (4) is far outside of the detection range (E).
